(19) United States
(12) Patent Application Publication
(10) Pub. No.: US 2025/0056841 A1
(43) Pub. Date: Feb. 13, 2025

(54) INTEGRATED CIRCUIT DEVICE AND MANUFACTURING METHOD THEREOF

(71) Applicants: TAIWAN SEMICONDUCTOR MANUFACTURING COMPANY, LTD., Hsinchu (TW); NATIONAL TAIWAN UNIVERSITY, TAIPEI (TW)

(72) Inventors: Jih-Chao CHIU, New Taipei City (TW); Chien-Te TU, Hsinchu City (TW); Yuan-Ming LIU, Taichung City (TW); Eknath SARKAR, New Taipei City (TW); Chee-Wee LIU, Taipei City (TW)

(73) Assignees: TAIWAN SEMICONDUCTOR MANUFACTURING COMPANY, LTD., Hsinchu (TW); NATIONAL TAIWAN UNIVERSITY, TAIPEI (TW)

(21) Appl. No.: 18/447,795

(22) Filed: Aug. 10, 2023

(51) Int. Cl. H01L 29/423; H01L 21/8238; H01L 27/092; H01L 29/06; H01L 29/66; H01L 29/775; H01L 29/786

(52) U.S. Cl. CPC H01L 29/42392; H01L 21/823807; H01L 27/092; H01L 29/0673; H01L 29/66439; H01L 29/775; H01L 29/78693; H01L 29/78696

(57) ABSTRACT

An integrated circuit device includes a semiconductor layer, an oxide semiconductor layer, and a gate structure. The semiconductor layer is free of oxygen. The oxide semiconductor layer is over and spaced apart from the semiconductor layer. The gate structure wraps around a channel region of the semiconductor layer and a channel region of the oxide semiconductor layer.

### BACKGROUND

The semiconductor industry has experienced rapid growth due to continuous improvements in the integration density of various electronic components (i.e., transistors, diodes, resistors, capacitors, etc.). For the most part, this improvement in integration density has come from repeated reductions in minimum feature size, which allows more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-14 illustrate a method of manufacturing an integrated circuit device at various stages in accordance with some embodiments.

FIG. 15 is a circuit diagram of the integrated circuit device of FIG. 14 in accordance with some embodiments of the present disclosure.

FIGS. 16A and 16B illustrate cross-sectional view of an integrated circuit device in accordance with some embodiments.

FIGS. 17-19B illustrate a method of manufacturing an integrated circuit device at various stages in accordance with some embodiments.

FIGS. 20-23 illustrate a method of manufacturing an integrated circuit device at various stages in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The term “multi-gate device” is used to describe a device (e.g., a semiconductor transistor) that has at least some gate material disposed on multiple sides of at least one channel of the device. In some examples, the multi-gate device may be referred to as a GAA device or a nanosheet device having gate material disposed on at least four sides of at least one channel of the device. The channel region may be referred to as a “nanowire,” which as used herein includes channel regions of various geometries (e.g., cylindrical, bar-shaped) and various dimensions. In some examples, the multi-gate device may be referred to as a FinFET device. However, one of ordinary skill would recognize that the teaching can apply to a single channel (e.g., single nanosheet) or any number of channels. One of ordinary skill may recognize other examples of semiconductor devices that may benefit from aspects of the present disclosure.

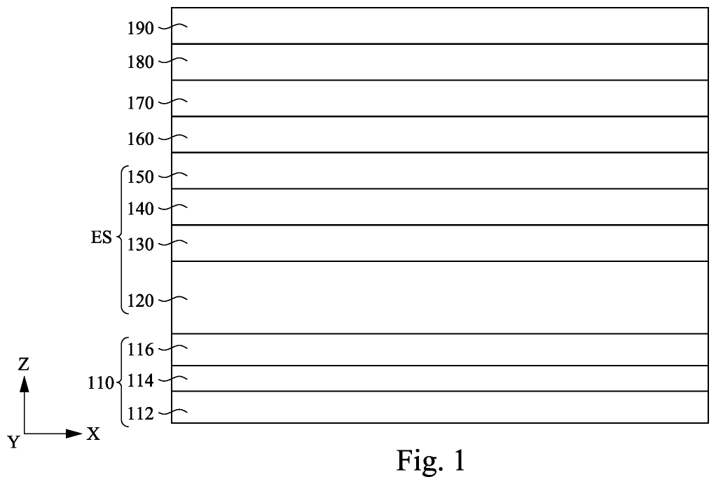

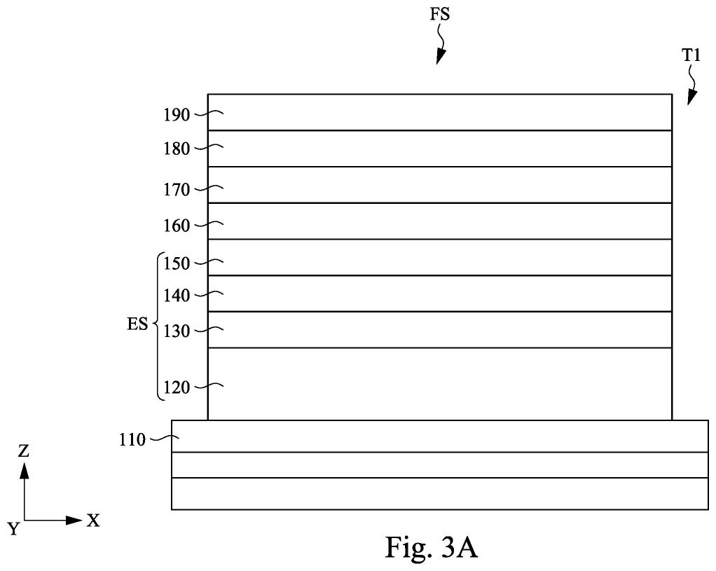

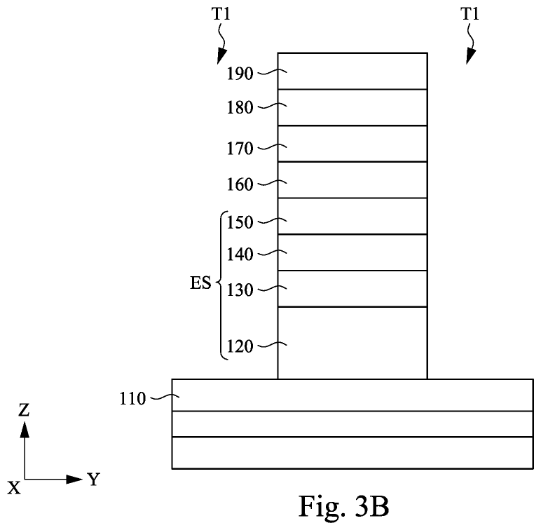

FIGS. 1-14 illustrate a method of manufacturing an integrated circuit device at various stages in accordance with some embodiments. FIGS. 1, 2, 3A, 4, 5, 6A, 7A, and 8-14 are cross-sectional views of the integrated circuit device (e.g., taken along line direction X, orthogonal to directions Y and Z) at various manufacturing stages in accordance with some embodiments. FIGS. 3B, 6B, and 7B, are cross-sectional views of the integrated circuit device (e.g., taken along direction Y, orthogonal to directions X and Z) at various manufacturing stages in accordance with some embodiments. It is understood that additional steps may be provided before, during, and after the steps shown in FIGS. 1-14, and some of the steps described below can be replaced or eliminated for additional embodiments of the method. The order of the operations/processes may be interchangeable.

Reference is made to FIG. 1. An epitaxial stack ES is formed over a substrate 110. In some embodiments, the substrate 110 may include silicon (Si). Alternatively, the substrate 110 may include germanium (Ge), silicon germanium (SiGe), a III-V material (e.g., GaAs, GaP, GaAsP, AlInAs, AlGaAs, GaInAs, InAs, GaInP, InP, InSb, and/or GaInAsP; or a combination thereof) or other appropriate semiconductor materials. In some embodiments, the substrate 110 may include a semiconductor-on-insulator (SOI) structure such as a buried dielectric layer 114 between a semiconductor substrate 112 and a semiconductor layer 116. The semiconductor substrate 112 and the semiconductor layer 116 may include Si, Ge, SiGe, a III-V material (e.g., GaAs, GaP, GaAsP, AlInAs, AlGaAs, GaInAs, InAs, GaInP, InP. InSb, and/or GaInAsP; or a combination thereof) or other appropriate semiconductor materials. Also, the substrate 110 may include a buried dielectric layer 114 such as a buried oxide (BOX) layer, such as that formed by a method referred to as separation by implantation of oxygen (SIMOX) technology, wafer bonding, selective epitaxial growth (SEG), or another appropriate method. The semiconductor layer 116 may be a monocrystalline layer thinned down to have a thickness in a range from about 1 nanometer to about 1000 nanometers.

The epitaxial stack ES includes a buffer layer 120, a semiconductor sacrificial layer 130, a semiconductor layer 140, and a semiconductor sacrificial layer 150 stacked in a sequence. In some embodiments, the semiconductor layer 140 may include suitable semiconductor material, such as group-IV semiconductor (e.g., Si, Ge, Sn, SiGe, GeSn), III-V semiconductor (e.g., GaAs), the like, or the combination thereof. The semiconductor layer 140 is substantially free of oxygen. The semiconductor layer 140 may be referred to as an oxygen-free semiconductor layer or a non-metal oxide semiconductor layer. In some embodiments, materials of the semiconductor layer 140 is selected for serving as a p-type channel for a p-type transistor. The semiconductor sacrificial layers 130 and 150 may have different semiconductor compositions from the semiconductor layer 140. For example, in some embodiments, the semiconductor sacrificial layers 130 and 150 may include Ge, and the semiconductor layer 140 includes GeₓSn₁₋ₓ, in which x is equal to or greater than 0, and less than 1. In some embodiments, the semiconductor sacrificial layers 130 and 150 may include Ge, and the semiconductor layer 140 includes Si₁₋ₓGeₓ, in which x is equal to or greater than 0, and less than 1.

The buffer layer 120 may include a suitable semiconductor material for confining defects of epitaxial material grown from the semiconductor substrate 112. For example, the buffer layer 120 may include Ge or other suitable material. In other words, the buffer layer 120 may relax the lattice mismatch between the semiconductor sacrificial layer 130 and the semiconductor substrate 112.

By way of example, epitaxial growth of the layers of the stack ES may be performed by a molecular beam epitaxy (MBE) process, a metalorganic chemical vapor deposition (MOCVD) process, and/or other suitable epitaxial growth processes. In some embodiments, the epitaxially grown layers such as, the epitaxial layers 120-150 include suitable semiconductor material, such as like Si, Ge, Sn, SiGe, GeSn, III-V semiconductor, the like, or the combination thereof. In some embodiments, the semiconductor layer 140 is substantially dopant-free (i.e., having an extrinsic dopant concentration from about 0 cm⁻³ to about 1×10¹⁸ cm⁻³), where for example, no intentional doping is performed during the epitaxial growth process. In some embodiments, the semiconductor sacrificial layers 130 and 150 may be intentionally doped with p-type dopants (e.g., boron), for example, with a dopant concentration from about 1×10¹⁸ cm⁻³ to about 1×10²² cm⁻³. In some embodiments, the buffer layer 120 is substantially dopant-free (i.e., having an extrinsic dopant concentration from about 0 cm⁻³ to about 1×10¹⁸ cm⁻³), where for example, no intentional doping is performed during the epitaxial growth process. It is noted that one semiconductor layer 140 and two semiconductor sacrificial layers 130 and 150 are alternately arranged as illustrated in FIG. 1, which is for illustrative purposes only and not intended to be limiting beyond what is specifically recited in the claims. It can be appreciated that any number of semiconductor layers 140 can be formed in the epitaxial stack ES. In some embodiments, the number of the semiconductor layers 140 is between 1 and 8. For example, the number of the semiconductor layers 140 is 1 in FIG. 1.

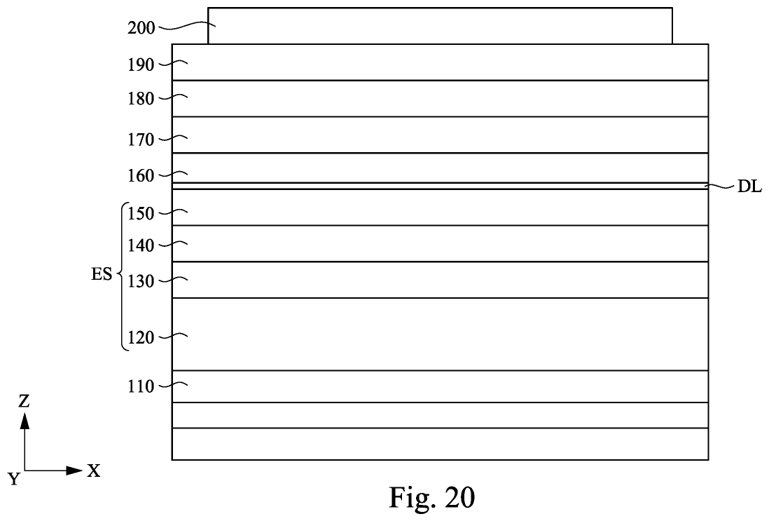

After the formation of the epitaxial stack ES, a sacrificial layer 160, an oxide semiconductor layer 170, a sacrificial layer 180, and a mask layer 190 are deposited over the epitaxial stack ES in a sequence. In some embodiments, the sacrificial layers 160 and 180 may include suitable dielectric/insulating material (e.g., silicon nitride, silicon oxide), suitable metals (e.g., TiN, W, Ti), the like, or the combination thereof. When the sacrificial layer 160 includes dielectric/insulating material, the sacrificial layer 160 may be referred to as an isolation layer electrically isolating upper materials from lower materials. Some other embodiment where the sacrificial layers 160 and 180 include suitable metal, a additional isolation layer may be formed between the metal sacrificial layer 160 and the sacrificial layer 150 for electrical isolation, which will described later in FIGS. 20-23. The oxide semiconductor layer 170 can be deposited at a low process temperature (e.g., in room temperature), thereby resulting in limited thermal budget and less impacts to the bottom material (e.g. the semiconductor layer 140). In some embodiments, the oxide semiconductor layer 170 may be referred to as a metal-oxide semiconductor layer. In some embodiments, metal-oxide semiconductors contain a metal cation (i.e., Zn, Sn, In, Cu, and Ni) and an oxide anion, including binary metal oxides (e.g., In₂O₃, ZnO), ternary metal oxides (e.g., InZnO(IZO), InSnO), and quaternary metal oxides (e.g., InGaZnO (IGZO)), the like, or the combination thereof. In the present embodiments, the oxide semiconductor layer 170 may have a fermi level that sits close to the conduction band, and therefore these materials are naturally n-type, and capable of serving as a n-type channel layer for an n-type device. The oxide semiconductor layer 170 is deposited by atomic layer deposition (ALD), sputter, the like, or the combination thereof. In the present embodiments, the oxide semiconductor layer 170 deposited over the sacrificial layer 160 may be at a uniform amorphous phase while retaining the high carrier mobility of oxide semiconductors. In some alternative embodiments, the oxide semiconductor layer 170 may be crystalline by tuning deposition parameters and post deposition annealing.

The sacrificial layer 180 may also be referred to as a mask layer. In some embodiments, the sacrificial layer 160 and the sacrificial layer 180 may include the same dielectric material. The mask layer 190 may include a suitable dielectric material different from that of the sacrificial layer 160 and the sacrificial layer 180. The mask layer 190 may include a suitable dielectric material, such as silicon nitride, silicon oxide, the like, or the combination thereof. The sacrificial layer 160, the sacrificial layer 180, and the mask layer 190 are deposited by plasma-enhanced chemical vapor deposition (PECVD), the like, or the combination thereof. It can be appreciated that any number of semiconductor layers 170 can be formed. In some embodiments, the number of the semiconductor layers 170 is between 1 and 8. For example, the number of the semiconductor layers 170 is 1 in FIG. 1.

The thickness of each of the buffer layer 120, the semiconductor sacrificial layer 130, the semiconductor layer 140, the semiconductor sacrificial layer 150, the sacrificial layer 160, the oxide semiconductor layer 170, the sacrificial layer 180, and the mask layer 190 may be in a range from about 1 nanometer to about 1 micrometer. In some embodiments, the oxide semiconductor layer 170 may have a thickness less than that of the semiconductor layer 140. In some other embodiments, the oxide semiconductor layer 170 may have a thickness comparable to or greater than that of the semiconductor layer 140. In some embodiments, the thickness of the layers 120, 130, 150, and 160 may be greater than the thickness of the oxide semiconductor layer 170 and the semiconductor layer 140.

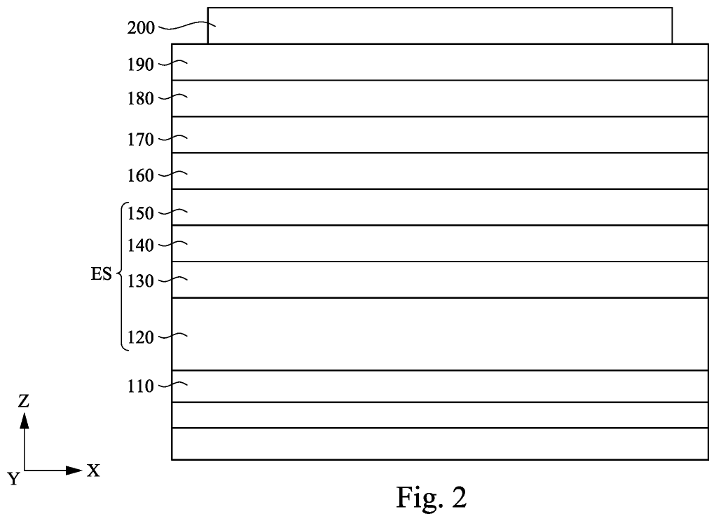

Reference is made to FIG. 2. A patterned mask 200 is formed by lithography process, such as photolithography process or e-beam lithography process. The photolithography process may include forming a photoresist layer (not shown) over the structure of FIG. 1, exposing the photoresist to a pattern, performing post-exposure bake processes, and developing the resist, thereby forming a patterned mask 200 including the resist. In some embodiments, a hard mask layer (not shown) may be formed over the structure of FIG. 1 prior to the formation of the photoresist layer (not shown) and patterned by an etching process after developing the resist, thereby forming a patterned mask 200 including a hard mask (e.g., silicon nitride).

Reference is made to FIGS. 3A and 3B. The patterned mask 200 may be used to protect regions of the layers formed on the substrate 110, while an etch process forms trenches T1 in unprotected regions through the hard mask layer, through the layers 120-190, thereby leaving a fin FS. The trenches T1 may be etched using a dry etch (e.g., reactive ion etching), a wet etch, and/or combination thereof. After the etching process, the patterned mask 200 (referring to FIG. 2) may be removed by suitable stripping, ashing, etching, cleaning process, like, or the combination thereof.

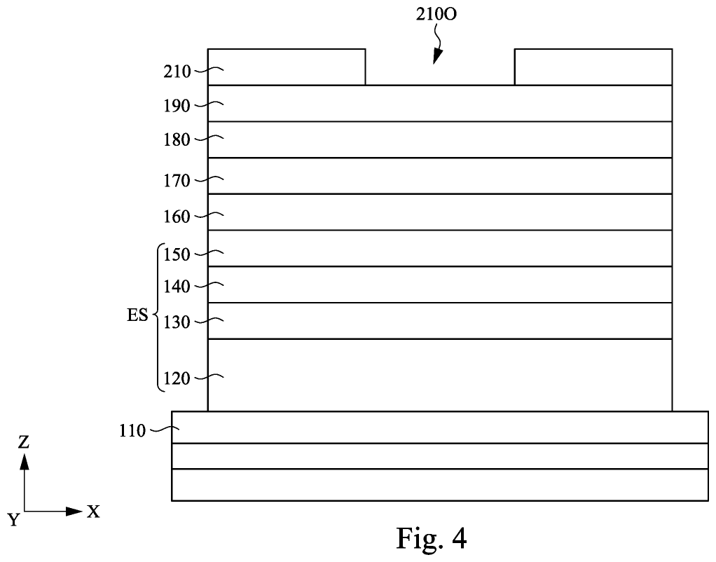

Reference is made to FIG. 4. A patterned mask 210 is formed by lithography process, such as photolithography process. The photolithography process may include forming a photoresist layer (not shown) over the structure of FIGS. 3A and 3B, exposing the photoresist to a pattern, performing post-exposure bake processes, and developing the resist, thereby forming a patterned mask 210 including the resist. In some embodiments, a hard mask layer (not shown) may be formed over the structure of FIGS. 3A and 3B prior to the formation of the photoresist layer (not shown) and patterned by an etching process after developing the resist, thereby forming a patterned mask 210 including a hard mask (e.g., silicon nitride). The patterned mask 210 may include an opening 2100 exposing the mask layer 190.

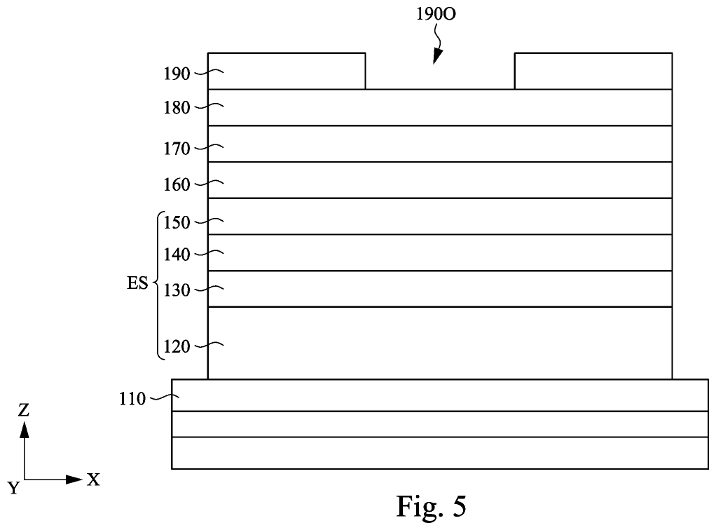

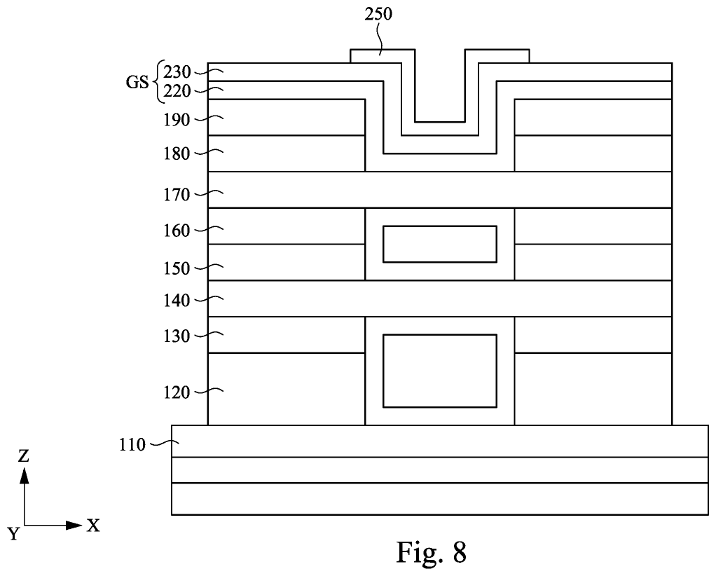

Reference is made to FIG. 5. An etching process is performed to remove a portion of the mask layer 190 exposed by the opening 2100 of the patterned mask 210 (referring to FIG. 4). Thus, the mask layer 190 has an opening 1900 exposing the underlying sacrificial layer 180. The etching process may have an etch selectivity between the mask layer 190 and the sacrificial layer 180, such that the sacrificial layer 180 may serve as an etch stop layer during the etching process. After the etching process, the patterned mask 210 (referring to FIG. 8) may be removed by suitable stripping, ashing, etching, or cleaning process.

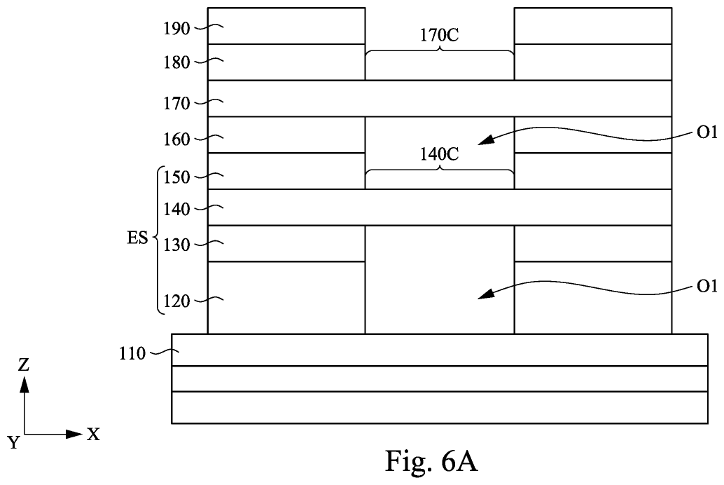

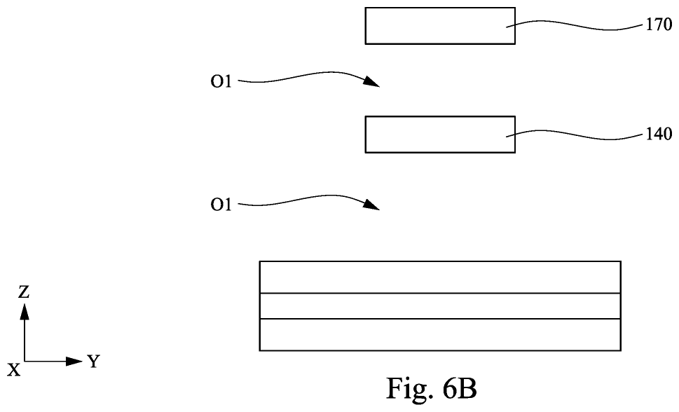

Reference is made to FIGS. 6A and 6B. A selective etching process is performed to remove a portion of the sacrificial layer 180 exposed by the opening 1900 of the mask layer 190 (referring to FIG. 5) and portions of the sacrificial layer 160, the semiconductor sacrificial layer 150, the semiconductor sacrificial layer 130, and the buffer layer 120 therebelow. The mask layer 190 may serve as an etch mask during the selective etching process. The selective etching process may etch materials of the sacrificial layers 160 and 180 at a faster rate than etch materials of the oxide semiconductor layer 170 and the semiconductor layer 140, thus resulting in openings/spaces O1 with a channel region 170C of the oxide semiconductor layer 170 exposed in the openings/spaces O1. Also, the selective etching process may etch materials of the semiconductor sacrificial layers 130 and 150 at a faster rate than etch materials of the oxide semiconductor layer 170 and the semiconductor layer 140, thus resulting in openings/spaces O1 with a channel region 140C of the semiconductor layer 140 exposed in the openings/spaces O1 while the oxide semiconductor layer 170 is not substantially etched. The openings/spaces O1 may expose sidewalls of the sacrificial layers 180 and the sacrificial layer 160, sidewalls of the semiconductor sacrificial layers 150, 130, and sidewalls of the buffer layer 120. In this way, the semiconductor layer 140 and the oxide semiconductor layer 170 become nanosheets suspended over the substrate 110. This step is also called a channel release process. At this interim processing step, the openings/spaces O1 between nanosheets may be filled with ambient environment conditions (e.g., air, nitrogen, etc). In some embodiments, the nanosheets can be interchangeably referred to as nanowires, nanoslabs and nanorings, depending on their geometry.

In the present embodiments, the selective etching process may use the same etch recipe for removing the portions of the sacrificial layers 160 and 180 (forming upper openings O1) and the portions of the semiconductor sacrificial layers 130 and 150 (forming lower openings O1) without substantially damaging the semiconductor layer 140 and the oxide semiconductor layer 170. For example, the selective etching process may be a dry etching process using the fluorine-based gas (e.g. SF₆). The selective etching process may be a (substantially) isotropic etching process. For example, the selective etching process may use fluorine-based plasma without substrate bias for substantially isotopically etching materials. With the isotropic etching process, plasma can laterally etch materials below the oxide semiconductor layer 170.

In some alternative embodiments, the removal of the portions of the sacrificial layers 160 and 180 may be separated from the removal of the portions of the semiconductor sacrificial layers 130 and 150. For example, a first selective etching process may use a first etch recipe for removing the portions of the sacrificial layers 160 and 180 (forming upper openings O1), and a second selective etching process may use a second etch recipe for removing the portions of the semiconductor sacrificial layers 130 and 150 (forming lower openings O1), in which the first etch recipe is different from the second etch recipe. After the etching process, openings O1 are formed around the semiconductor layers 130 and 170.

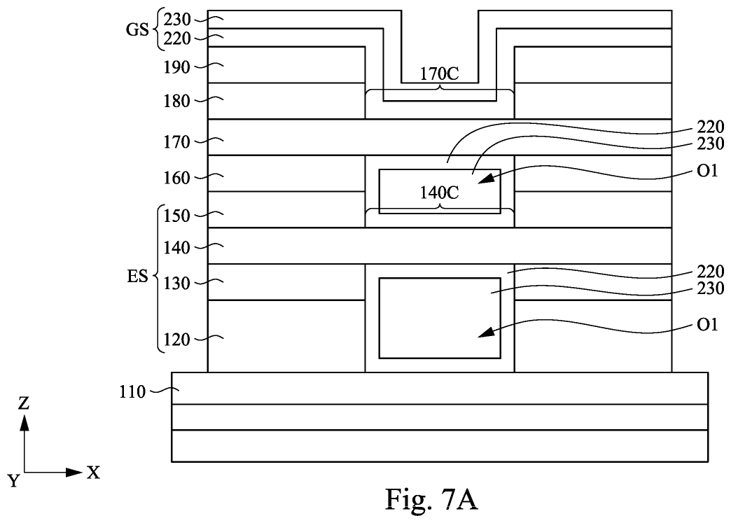

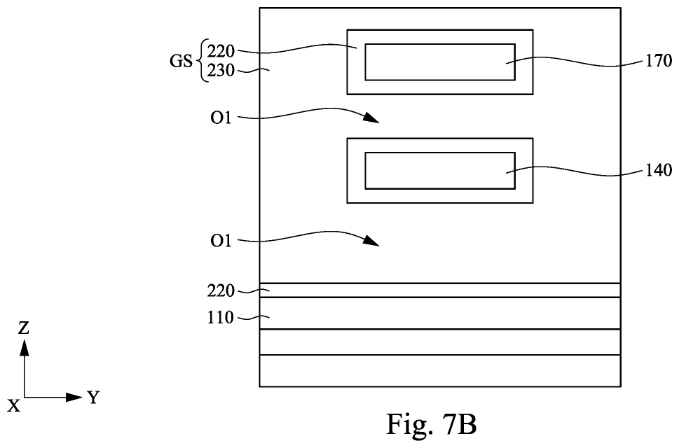

Reference is made to FIGS. 7A and 7B. A gate structures GS is formed in the openings O1 to surround each of the nanosheets (e.g., the semiconductor layer 140 and the oxide semiconductor layer 170). The gate structures GS may be final gates of GAA FETs. The final gate structure may be a high-k/metal gate stack, however other compositions are possible. In some embodiments, each of the gate structures GS forms the gate associated with the channel region 140C of the semiconductor layer 140 and the channel region 170C of the oxide semiconductor layer 170. For example, the high-k/metal gate structures GS are formed within the openings/spaces O1 provided by the release of the semiconductor layer 140 and the oxide semiconductor layer 170. In some embodiments, the high-k/metal gate structure GS wrapping around the channel region 140C of the semiconductor layer 140 is continuously connected with the high-k/metal gate structure GS wrapping around the channel region 170C of the oxide semiconductor layer 170.

In various embodiments, the high-k/metal gate structure GS includes a high-k gate dielectric layer 220 formed around the semiconductor layers 140 and the oxide semiconductor layers 170 and a gate metal layer 230 formed around the high-k dielectric layer 220. Formation of the high-k/metal gate structures GS may include one or more deposition processes (e.g., ALD. CVD, physical vapor deposition (PVD), the like, or the combination thereof) to form various gate materials, resulting in the high-k/metal gate structures GS.

In some embodiments, the high-k gate dielectric layer 220 includes dielectric materials such as hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO; HZO), lanthanum oxide (LaO), zirconium oxide (ZrO₂), titanium oxide (TiO₂), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), the like, or combinations thereof. In some embodiments, the gate metal layer 230 may include one or more work function metal layers stacked one over another. The one or more work function metal layers in the gate metal layer 230 provide a suitable work function for the high-k/metal gate structures GS. In some embodiments, the gate metal layer 230 may include a fill metal formed after the formation of the work function metal layers. In some embodiments, the gate metal layer 230 may exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAlN, or other suitable materials.

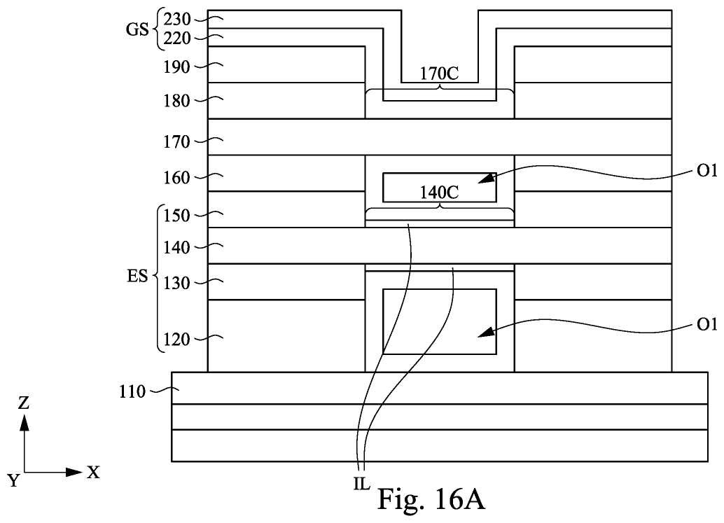

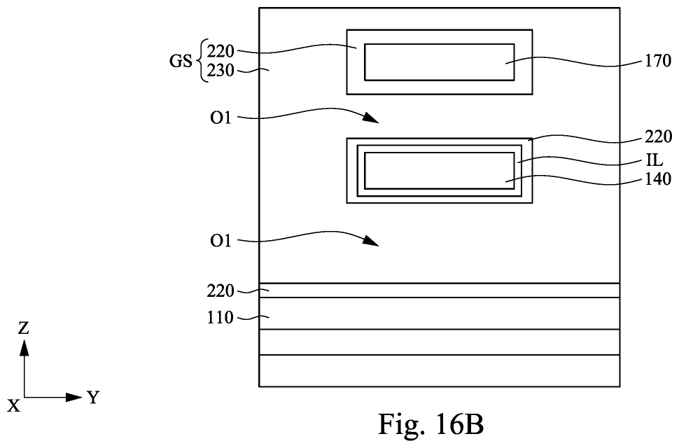

In some embodiments, the high-k gate dielectric layer 220 of the high-k/metal gate structure GS may be in direct contact with the oxide semiconductor layer 170. That is, no additional oxide is formed between the high-k gate dielectric layer 220 and the oxide semiconductor layer 170. Furthermore, in some embodiments, the high-k gate dielectric layer 220 of the high-k/metal gate structure GS may be in direct contact with the semiconductor layer 140, which indicates no additional oxide is formed between the high-k gate dielectric layer 220 and the semiconductor layer 140. In some alternative embodiments, interfacial layers (oxides) may be formed between the high-k gate dielectric layer 220 and the channel region 140C of the semiconductor layer 140, which is illustrated later in FIGS. 16A and 16B.

In some embodiments, the selective etching process in FIGS. 6A and 6B and the formation of the high-k/metal gate structure GS in FIGS. 7A and 7B in combination may be referred to as a gate replacement process. The gate replacement process includes replacing a portion of the semiconductor sacrificial layer 130, a portion of the semiconductor sacrificial layer 150, a portion of the sacrificial layer 160, and a portion of the sacrificial layer 180 that vertically overlaps the channel regions 140C and 170C with the high-k/metal gate structure GS.

Reference is made to FIG. 8. A patterned mask 250 is formed by lithography process, such as photolithography process. The photolithography process may include forming a photoresist layer (not shown) over the structure of FIGS. 7A and 7B, exposing the photoresist to a pattern, performing post-exposure bake processes, and developing the resist, thereby forming a patterned mask 250 including the resist. In some embodiments, a hard mask layer (not shown) may be formed over the structure of FIGS. 7A and 7B prior to the formation of the photoresist layer (not shown) and patterned by an etching process after developing the resist, thereby forming a patterned mask 250 including a hard mask (e.g., silicon nitride).

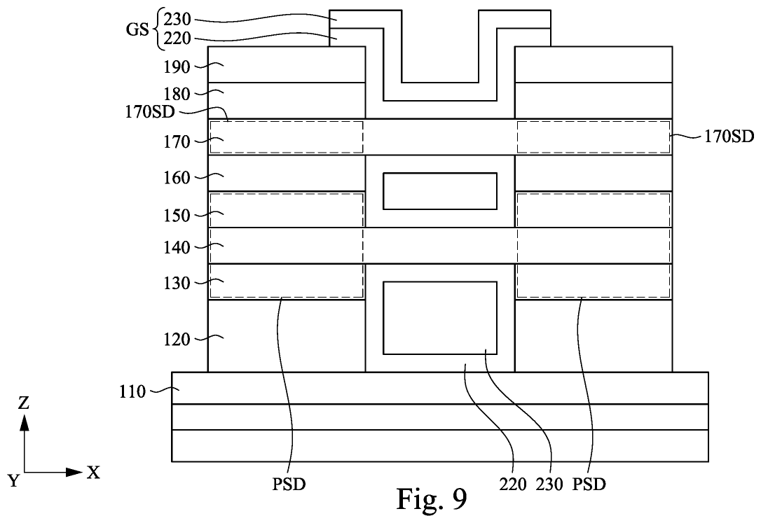

Reference is made to FIG. 9. The gate structures GS is patterned by an etching process using the patterned mask 250 (referring to FIG. 8) as an etch mask, such that portions of the mask layer 190 unprotected by the patterned mask 250 (referring to FIG. 8) are exposed. After the patterning process, the patterned mask 250 (referring to FIG. 8) may be removed by suitable stripping, ashing, etching, or cleaning process.

In some embodiments, before or after the channel release process, or before or after the formation of the patterned gate structures GS, source/drain regions 170SD may be formed in the oxide semiconductor layer 170 by hydrogen diffusion, plasma treatment, or other suitable process. In some embodiments, while the end portion of the semiconductor layer 140 is sandwiched between the intentionally doped semiconductor sacrificial layers 130 and 150, source/drain regions PSD may be formed on opposite sides of the channel region 140C of the semiconductor layer 140 wrapped by the high-k/metal gate structure GS. The source/drain regions PSD may include the intentionally doped semiconductor sacrificial layers 130 and 150 and a source/drain region of the semiconductor layer 140, which may be doped by diffusion from the semiconductor sacrificial layers 130 and 150 in above one or more process steps. The sacrificial layer 160 may isolate the source/drain regions PSD on opposite sides of the channel region 140C from the source/drain regions 170SD on opposite sides of the channel region 170C of the oxide semiconductor layer 170.

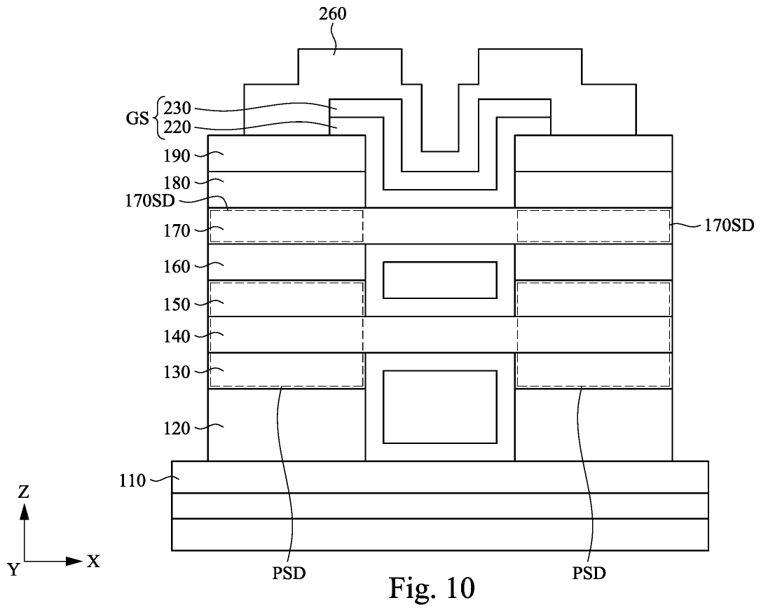

Reference is made to FIG. 10. A patterned mask 260 is formed by lithography process, such as photolithography process. The photolithography process may include forming a photoresist layer (not shown) over the structure of FIG. 9, exposing the photoresist to a pattern, performing post-exposure bake processes, and developing the resist, thereby forming a patterned mask 260 including the resist. In some embodiments, a hard mask layer (not shown) may be formed over the structure of FIG. 9 prior to the formation of the photoresist layer (not shown) and patterned by an etching process after developing the resist, thereby forming a patterned mask 260 including a hard mask (e.g., silicon nitride).

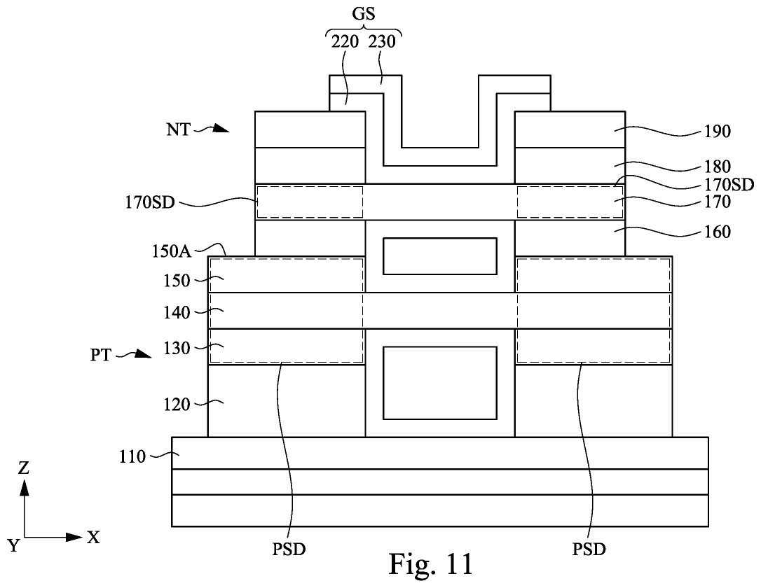

Reference is made to FIG. 11. The patterned mask 260 (referring to FIG. 10) may be used to protect regions of the substrate 110, and layers formed thereupon, while an etch process removes materials of the layers 160-190 in unprotected regions, thereby leaving a top surface of the semiconductor sacrificial layer 150 exposed. The etch process may be etched using a dry etch (e.g., reactive ion etching), a wet etch, and/or combination thereof. The etch process may use buffered oxide etchant (BOE). The semiconductor sacrificial layer 150 may have a higher etch resistance to the etchant than the layers 160-190, and therefore can serve as an etch stop layer during the etching process. After the etching process, the patterned mask 260 (referring to FIG. 10) may be removed by suitable stripping, ashing, etching, or cleaning process.

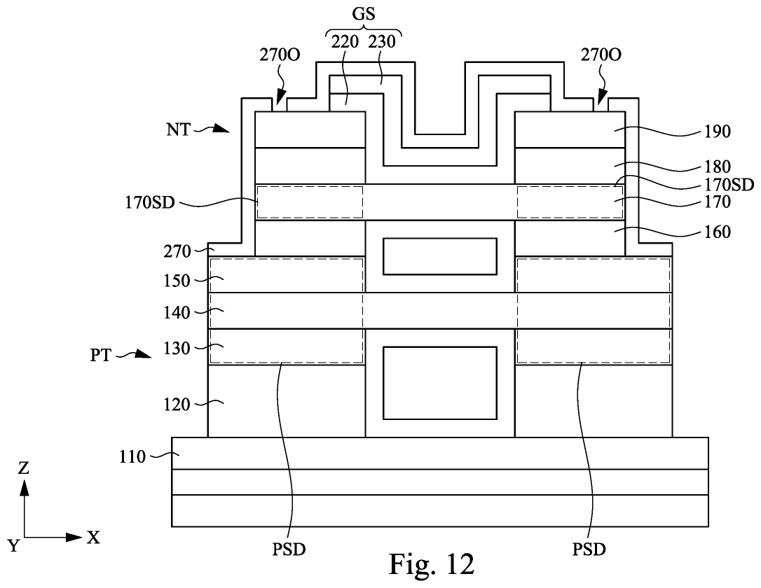

Reference is made to FIG. 12. A patterned mask 270 is formed by lithography process, such as photolithography process. The photolithography process may include forming a photoresist layer (not shown) over the structure of FIG. 11, exposing the photoresist to a pattern, performing post-exposure bake processes, and developing the resist, thereby forming a patterned mask 270 including the resist. In some embodiments, a hard mask layer (not shown) may be formed over the structure of FIG. 11 prior to the formation of the photoresist layer (not shown) and patterned by an etching process after developing the resist, thereby forming a patterned mask 270 including a hard mask (e.g., silicon nitride).

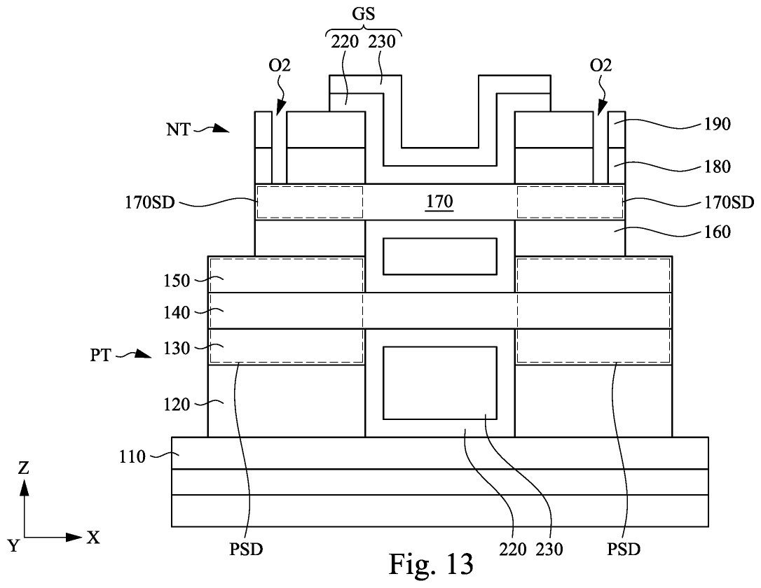

Reference is made to FIG. 13. The layers 180 and 190 are patterned by an etching process using the patterned mask 270 (referring to FIG. 12) as an etch mask, such that openings O2 are formed through the layers 180 and 190, leaving the oxide semiconductor layers 170 exposed.

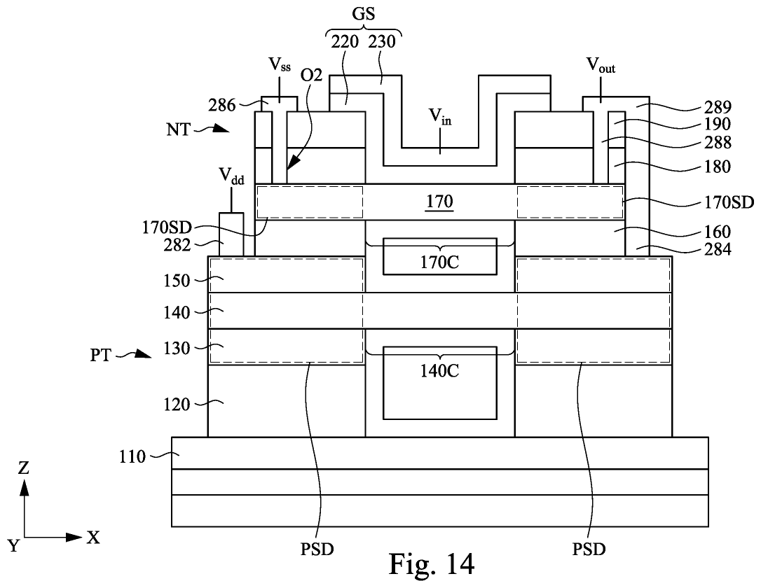

Reference is made to FIG. 14. Source/drain contacts 282 and 284 are formed over the semiconductor sacrificial layer 150 and in contact with the source/drain regions PSD, and source/drain contacts 286 and 288 are formed into the openings O2, over and in contact with the source/drain regions 170SD of the oxide semiconductor layer 170. Formation of the source/drain contacts 282, 284, 286, and 288 includes depositing a conductive layer over the semiconductor sacrificial layer 150 and into the openings O2 followed by a patterning process. The conductive layer may include suitable conductive materials, such as TiN, W. Pt, copper, the like, or the combination thereof. The conductive layer may include one or more conductive layers. Portions of the conductive layer in the openings O2 form the source/drain contacts 286, 288, and conductive lines 289. The patterning process may include lithography and etching process. By patterning a portion of the conductive layer external to the openings O2, the source/drain contacts 282 and 284 and a conductive line 289 are formed. In the present embodiments, the conductive line 289 may connect the source/drain contact 284 to the source/drain contact 288, thereby establishing an electrical connection for device circuits. In some other embodiments, the conductive line 289 may be arrange in another manner depending on device requirement.

In a complementary FET (CFET) architecture of FIG. 14, a p-type transistor PT and a n-type transistor NT are stacked on top of each other. The p-type transistor PT includes a channel (i.e., the channel region 140C of the semiconductor layer 140 wrapped by the high-k/metal gate structure GS), source/drain regions PSD on opposite sides of the channel, and a high-k/metal gate structure GS. The n-type transistor NT includes a channel (i.e., the channel region 170C of the oxide semiconductor layer 170 wrapped by the high-k/metal gate structure GS), source/drain regions 170SD on opposite sides of the channel, and a high-k/metal gate structure GS. The sacrificial layer 160 may isolate the p-type transistor PT from the n-type transistor NT.

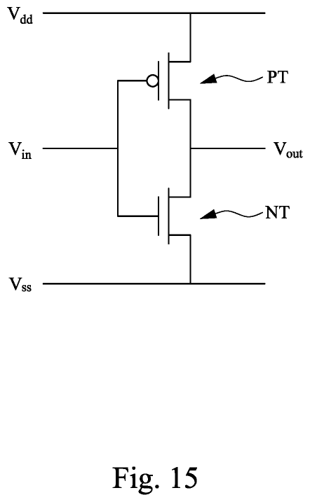

FIG. 15 is a circuit diagram of the integrated circuit device of FIG. 14 in accordance with some embodiments of the present disclosure. As the p-type transistor PT and the n-type transistor NT share the gate structure GS, and the source/drain contacts 284 and 288 are connected, the p-type transistor PT and the n-type transistor NT are coupled with each other to form an inverter. In the present embodiments, the potential Vₛₛ and V_{dd} are provided to the transistors NT and PT. Through the configuration, the output of the invertor circuit at node Vₒᵤₜ is the opposite of its input at the node Vᵢₙ.

FIGS. 16A and 16B illustrate cross-sectional view of an integrated circuit device, respectively taken along directions X and Y, in accordance with some embodiments. FIGS. 16A and 16B illustrate another configuration of the high-k/metal gate structures GS according to some embodiments of the present disclosure. In the present embodiments, the high-k/metal gate structure GS may further include an interfacial layer IL formed on exposed surfaces of the semiconductor layer 140. In some embodiments, the interfacial layer IL is oxide formed on exposed surfaces of semiconductor materials in the openings O1 by using, for example, thermal oxidation, chemical oxidation, wet oxidation or the like. As a result, surface portions of the semiconductor layer 140 exposed in the openings O1 are oxidized into semiconductor oxide to form an interfacial layer IL. In the present embodiments, the oxide semiconductor layer 170 may be free of the oxidation, so no additional oxide is formed on exposed surface portions of the oxide semiconductor layer 170. After the formation of the interfacial layer IL, gate materials of the high-k gate dielectric layer 220 and the gate metal layer 230 are deposited, resulting in the high-k/metal gate structures GS. In FIGS. 16A and 16B, with the presence of the interfacial layer IL, the high-k gate dielectric layer 220 may be spaced apart from the semiconductor layer 140 by the interfacial layer IL, but in direct contact with the oxide semiconductor layer 170. Other details of the present embodiments are similar to those illustrated in FIGS. 1-14, and thus not repeated herein.

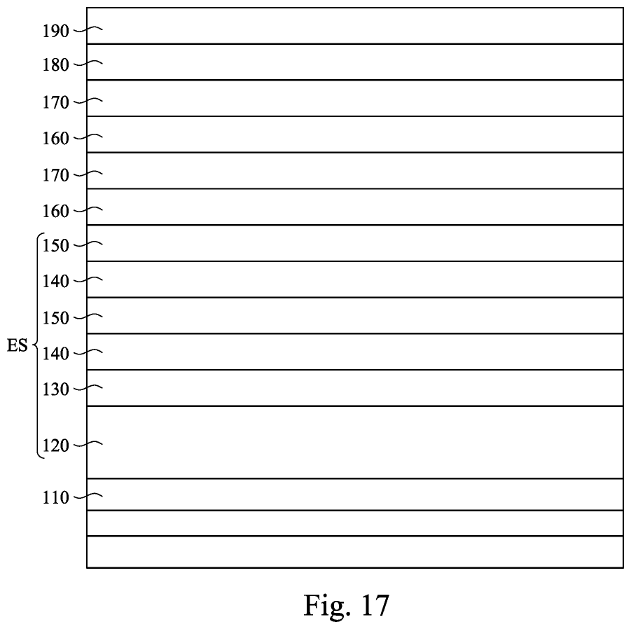

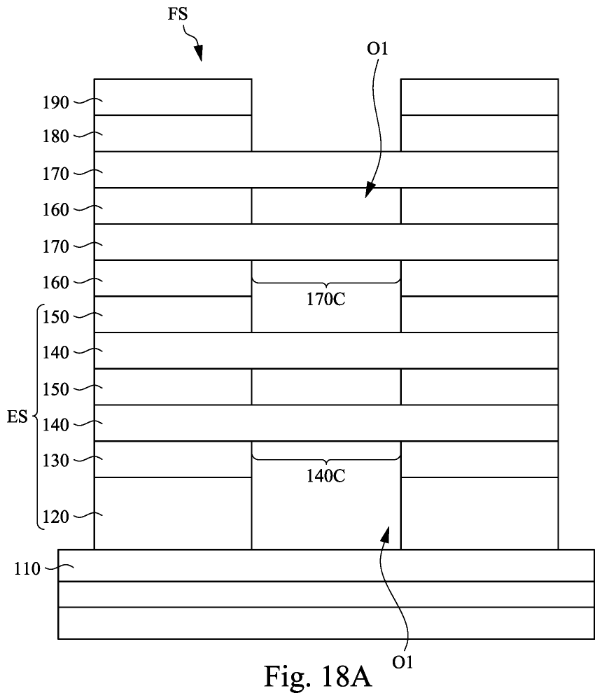

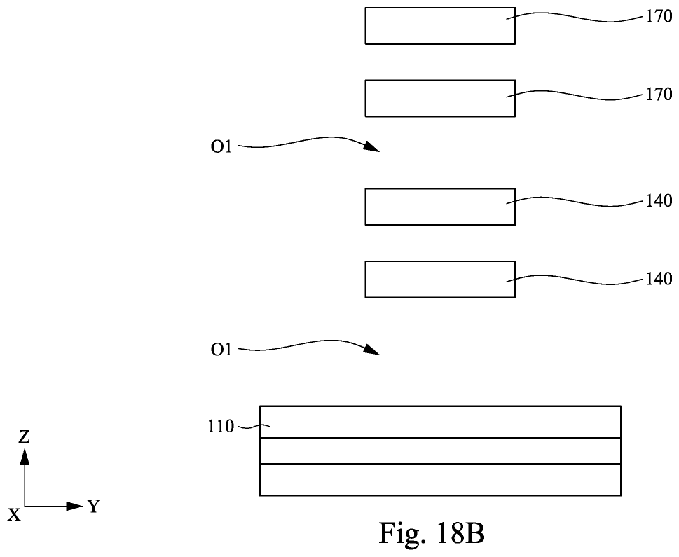

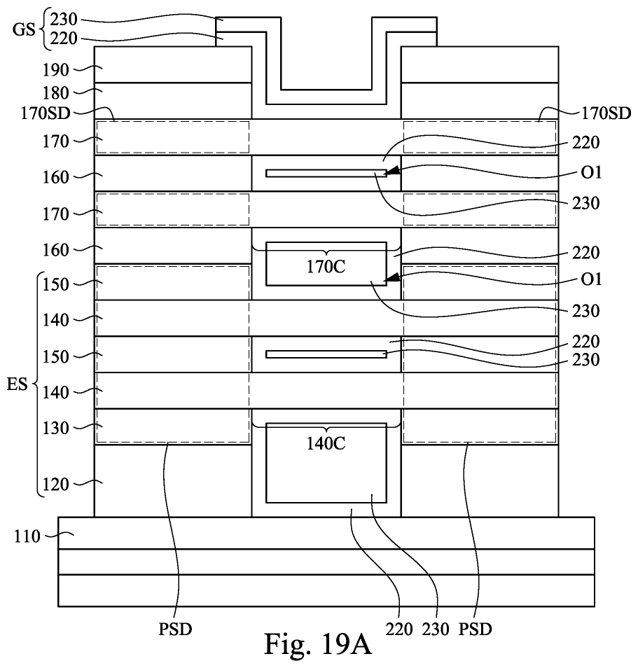

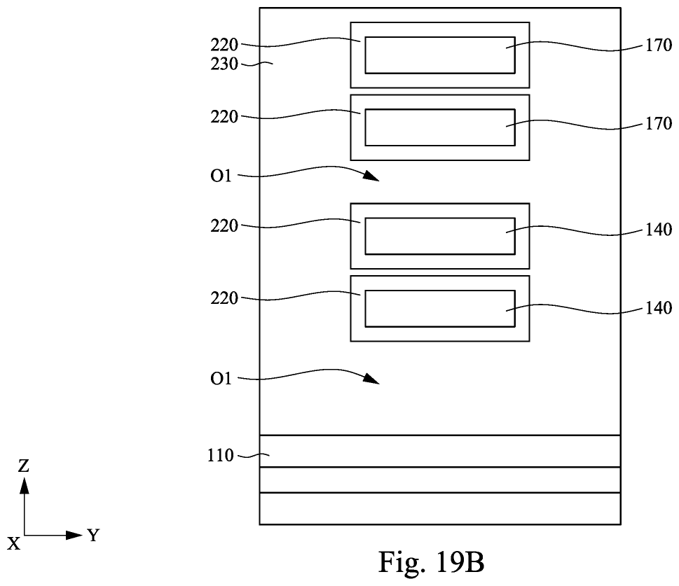

FIGS. 17-19B illustrate a method of manufacturing an integrated circuit device at various stages in accordance with some embodiments. Details of the present embodiments are similar to that of FIGS. 1-14, except that the number of the semiconductor layers 140 is greater than 1 (for example, 2), and the number of the semiconductor layers 170 is greater than 1 (for example, 2). FIGS. 17, 18A, and 19A are cross-sectional views of the integrated circuit device (e.g., taken along line direction X, orthogonal to directions Y and Z) at various manufacturing stages in accordance with some embodiments. FIGS. 18B and 19B are cross-sectional views of the integrated circuit device (e.g., taken along direction Y, orthogonal to directions X and Z) at various manufacturing stages in accordance with some embodiments. It is understood that additional steps may be provided before, during, and after the steps shown in FIGS. 17-19B, and some of the steps described below can be replaced or eliminated for additional embodiments of the method. The order of the operations/processes may be interchangeable.

Reference is made to FIG. 17. The epitaxial stack ES includes semiconductor sacrificial layers 130 and 150 alternatively arranged with the semiconductor layers 140. For example, in FIG. 17, a semiconductor sacrificial layer 130 is epitaxially deposited over the buffer layer 120, a lower semiconductor layer 140 is epitaxially deposited over the semiconductor sacrificial layer 130, a lower semiconductor sacrificial layer 150 is epitaxially deposited over the lower oxide semiconductor layer 140, and an upper semiconductor layer 140 is epitaxially deposited over the lower semiconductor sacrificial layer 150, an upper semiconductor sacrificial layer 150 is epitaxially deposited over the upper semiconductor layer 140. In some embodiments, the semiconductor layer 140 may include suitable semiconductor material, such as IV semiconductor (e.g., Si, Ge, Sn, SiGe, GeSn), III-V semiconductor (e.g., GaAs), the like, or the combination thereof. The semiconductor sacrificial layers 130 and 150 may have different semiconductor compositions from the semiconductor layer 140. By way of example, epitaxial growth of the layers of the stack ES may be performed by a molecular beam epitaxy (MBE) process, a metalorganic chemical vapor deposition (MOCVD) process, and/or other suitable epitaxial growth processes. In some embodiments, the epitaxially grown layers such as, the epitaxial layers 120-150 include suitable semiconductor material, such as like Si, Ge, Sn, SiGe, GeSn, III-V semiconductor, the like, or the combination thereof. The semiconductor layer 140 is substantially dopant-free. The semiconductor sacrificial layers 130 and 150 may be intentionally doped with p-type dopants (e.g., boron). It is noted that two semiconductor layer 140 and three semiconductor sacrificial layers 130 and 150 are alternately arranged as illustrated in FIG. 17, which is for illustrative purposes only and not intended to be limiting beyond what is specifically recited in the claims.

After the formation of the epitaxial stack ES, the sacrificial layers 160 and the oxide semiconductor layers 170 are alternatively deposited over the epitaxial stack ES, followed by the deposition of the sacrificial layer 180 and the mask layer 190. For example, in FIG. 17, a lower sacrificial layer 160 is deposited over the epitaxial stack ES, a lower oxide semiconductor layer 170 is deposited over the lower sacrificial layer 160, an upper sacrificial layer 160 is deposited over the lower oxide semiconductor layer 170, and then an upper oxide semiconductor layer 170 is deposited over the upper sacrificial layer 160. It is noted that two oxide semiconductor layer 170 and three layers 160/180 are alternately arranged as illustrated in FIG. 17, which is for illustrative purposes only and not intended to be limiting beyond what is specifically recited in the claims.

Reference is made to FIGS. 18A and 18B. The epitaxial stack ES and the layers thereon are patterned into a fin FS, as the step illustrated in FIGS. 2-3B. Then, a channel release process is performed as illustrated in FIGS. 4-6B. The channel release process is performed by a selective etching process removes a portion of the sacrificial layer 180 exposed by the opening 1900 of the mask layer 190 (referring to FIG. 5) and portions of the sacrificial layers 160, the semiconductor sacrificial layers 150, the semiconductor sacrificial layer 130, and the buffer layer 120 therebelow. As illustrated above, the selective etching process may etch materials of the sacrificial layers 160 and 180 at a faster rate than etch materials of the oxide semiconductor layer 170 and the semiconductor layer 140, thus resulting in openings/spaces O1 with channel regions of the oxide semiconductor layer 170 exposed in the openings/spaces O1. Also, the selective etching process may etch materials of the semiconductor sacrificial layers 130 and 150 at a faster rate than etch materials of the oxide semiconductor layer 170 and the semiconductor layer 140, thus resulting in openings/spaces O1 with channel regions of the semiconductor layers 140 exposed in the openings/spaces O1 while the oxide semiconductor layers 170 are not substantially etched. The openings/spaces O1 may expose sidewalls of the sacrifical layers 180, 160, sidewalls of the semiconductor sacrificial layers 150, 130, and sidewalls of the buffer layer 120. In this way, the semiconductor layers 140 and the oxide semiconductor layers 170 become nanosheets suspended over the substrate 110.

Reference is made to FIGS. 19A and 19B. A gate structure GS is formed in the openings O1 to surround each of the nanosheets (e.g., the semiconductor layers 140 and the oxide semiconductor layers 170). For example, the high-k/metal gate structures GS are formed within the openings/spaces O1 provided by the release of semiconductor layers 140 and the oxide semiconductor layers 170. In some embodiments, the high-k/metal gate structures GS wrapping around the channel regions 140C of the semiconductor layers 140 is continuously connected with the high-k/metal gate structure GS wrapping around the channel regions 170C of the oxide semiconductor layers 170.

In some embodiments, the selective etching process in FIGS. 18A and 18B and the formation of the high-k/metal gate structure GS in FIGS. 19A and 19B in combination may be referred to as a gate replacement process. The gate replacement process includes replacing a portion of the semiconductor sacrificial layer 130, portions of the semiconductor sacrificial layers 150, portions of the sacrificial layers 160, and a portion of the sacrificial layer 180 that vertically overlaps the channel regions 140C and 170C with the high-k/metal gate structure GS. Other details of the present embodiments are similar to those of FIGS. 1-14, and thereto not repeated herein.

In some embodiments, before or after the channel release process, or before or after the formation of the patterned gate structures GS, source/drain regions 170SD may be formed in the oxide semiconductor layer 170 by hydrogen diffusion, plasma treatment, or other suitable process. In some embodiments, while the end portion of the semiconductor layer 140 is sandwiched between the intentionally doped semiconductor sacrificial layers 130 and 150, source/drain regions PSD may be formed on opposite sides of the channel region 140C of the semiconductor layer 140 wrapped by the high-k/metal gate structure GS. The source/drain regions PSD may include the intentionally doped semiconductor sacrificial layers 130 and 150 and source/drain regions of the semiconductor layers 140, which may be doped by diffusion p-type dopants from the semiconductor sacrificial layers 130 and 150 in above one or more process steps. The sacrificial layer 160 may isolate the source/drain regions PSD on opposite sides of the channel region 140C from the source/drain regions 170SD on opposite sides of the channel region 170C of the oxide semiconductor layer 170.

In the complementary FET (CFET) architecture of FIGS. 17-19B, a p-type transistor PT and a n-type transistor NT are stacked on top of each other. The p-type transistor PT includes two channels (i.e., the two channel regions 140C of the semiconductor layer 140 wrapped by the high-k/metal gate structure GS), source/drain regions PSD on opposite sides of the channels, and a high-k/metal gate structure GS. The n-type transistor NT includes two channels (i.e., the two channel regions 170C of the oxide semiconductor layer 170 wrapped by the high-k/metal gate structure GS), source/drain regions 170SD on opposite sides of the channel, and a high-k/metal gate structure GS. The sacrificial layer 160 may isolate the p-type transistor PT from the n-type transistor NT.

FIGS. 20-23 illustrate a method of manufacturing an integrated circuit device at various stages in accordance with some embodiments. Details of the present embodiments are similar to that of FIGS. 1-14, except that the sacrificial layers 160 and 180 includes metal, such as TiN, W. Ti, the like, or the combination thereof. It is understood that additional steps may be provided before, during, and after the steps shown in FIGS. 20-23, and some of the steps described below can be replaced or eliminated for additional embodiments of the method. The order of the operations/processes may be interchangeable.

Reference is made to FIG. 20. In the present embodiments, an isolation layer DL may be deposited over the semiconductor sacrificial layer 150, followed by the deposition of the metal sacrificial layer 160. The isolation layer DL may include suitable dielectric/insulating material, such as silicon nitride, silicon oxide, the like, or the combination thereof. With the presence of the isolation layer DL, the metal sacrificial layer 160 can be electrically isolated from the underlying semiconductor sacrificial layer 150. The oxide semiconductor layer 170, a metal sacrificial layer 180, and a mask layer 190 are deposited over the metal sacrificial layer 160 in a sequence. A patterned mask 200 is then formed over the mask layer 190.

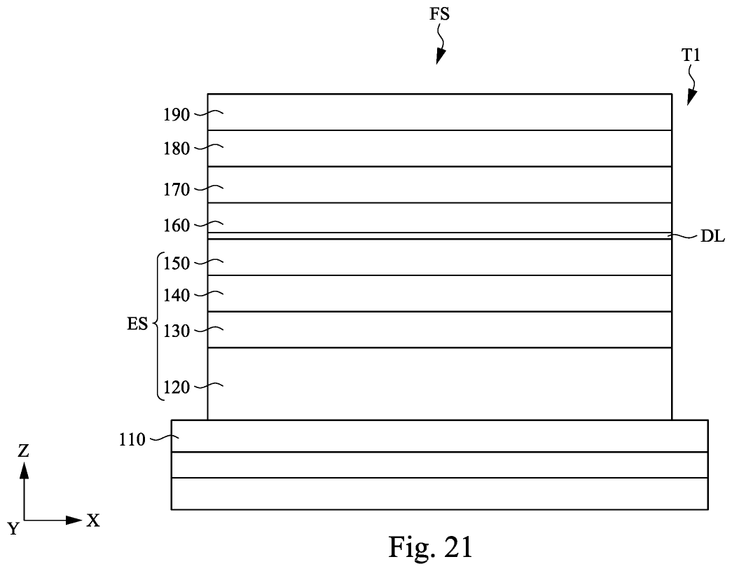

Reference is made to FIG. 21. The patterned mask 200 may be used to protect regions of the layers formed on the substrate 110, while an etch process forms trenches T1 in unprotected regions through the layers 120-190 and the isolation layer DL, thereby leaving a fin FS. The trenches T1 may be etched using a dry etch (e.g., reactive ion etching), a wet etch, and/or combination thereof. After the etching process, the patterned mask 200 (referring to FIG. 2) may be removed by suitable stripping, ashing, etching, cleaning process, like, or the combination thereof.

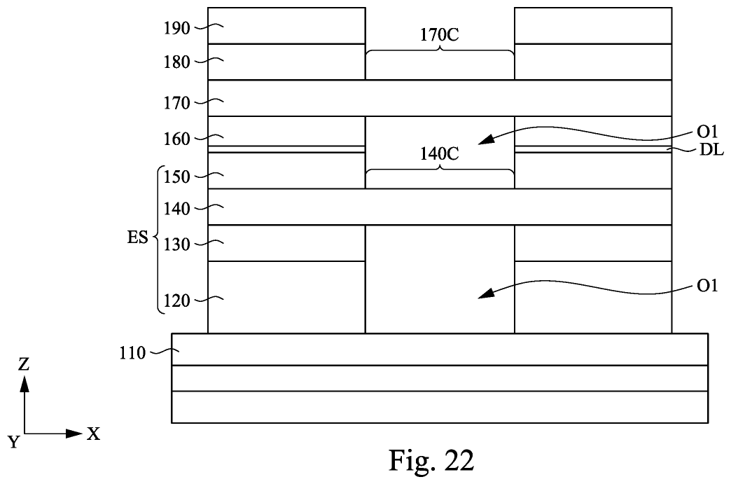

Reference is made to FIG. 22. A selective etching process is performed to remove portions of the metal sacrificial layer 180, the metal sacrificial layer 160, the dielectric layer DL, the semiconductor sacrificial layer 150, the semiconductor sacrificial layer 130, and the buffer layer 120 therebelow. The selective etching process may etch materials of the metal sacrificial layers 160 and 180 at a faster rate than etch materials of the oxide semiconductor layer 170 and the semiconductor layer 140, thus resulting in openings/spaces O1 with a channel region 170C of the oxide semiconductor layer 170 exposed in the openings/spaces O1. The selective etching process may etch the dielectric layer DL at a faster rate than etch materials of the oxide semiconductor layer 170 and the semiconductor layer 140, thus exposing the underlying epitaxial stack ES. Also, the selective etching process may etch materials of the semiconductor sacrificial layers 130 and 150 at a faster rate than etch materials of the oxide semiconductor layer 170 and the semiconductor layer 140, thus resulting in openings/spaces O1 with a channel region 140C of the semiconductor layer 140 exposed in the openings/spaces O1 while the oxide semiconductor layer 170 is not substantially etched. The selective etching process may use the same or different etch recipes for removing the portions of the metal sacrificial layer 180, the metal sacrificial layer 160, the dielectric layer DL, the semiconductor sacrificial layer 150, the semiconductor sacrificial layer 130, and the buffer layer 120.

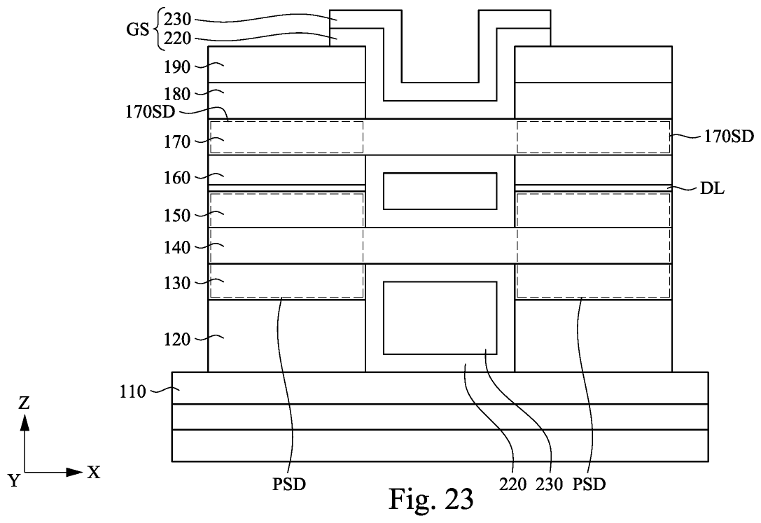

Reference is made to FIG. 23. A gate structures GS is formed in the openings O1 to surround each of the nanosheets (e.g., the semiconductor layer 140 and the oxide semiconductor layer 170). The gate structures GS may be final gates of GAA FETs. The final gate structure may be a high-k/metal gate stack, however other compositions are possible. In some embodiments, each of the gate structures GS forms the gate associated with the channel region 140C of the semiconductor layer 140 and the channel region 170C of the oxide semiconductor layer 170. Other details of the present embodiments are similar to those illustrated in FIGS. 1-14, and therefore not repeated herein.

Based on the above discussions, it can be seen that the present disclosure offers advantages. It is understood, however, that other embodiments may offer additional advantages, and not all advantages are necessarily disclosed herein, and that no particular advantage is required for all embodiments. One advantage is that a multilayer structure is designed to fabricate NFET with oxide semiconductor channel and PFET with Group IV channels using sacrificial insulator to isolate each other. Another advantage is that oxide semiconductor can be deposited at a low process temperature (e.g., in room temperature), resulting in limited thermal budget and less impacts to the bottom material (e.g. GeSn). Still another advantage is that the channel release of nFET and pFET can be done in the same recipe. Still another advantage is that the isolation process between the nFET and pFET is simple.

According to some embodiments of the present disclosure, an integrated circuit device includes a semiconductor layer free of oxygen; an oxide semiconductor layer over and spaced apart from the semiconductor layer; and a gate structure wrapping around a channel region of the semiconductor layer and a channel region of the oxide semiconductor layer.

According to some embodiments of the present disclosure, an integrated circuit device includes a p-type transistor, wherein the p-type transistor comprises at least one group-IV semiconductor layer and a first gate structure wrapping around the at least one group-IV semiconductor layer; an isolation layer over the p-type transistor; and a n-type transistor vertically stacked over the p-type transistor and over the isolation layer, wherein the n-type transistor comprises at least one oxide semiconductor layer and a second gate structure wrapping around the at least one oxide semiconductor layer.

According to some embodiments of the present disclosure, a method for manufacturing an integrated circuit device is provided. The method includes depositing an epitaxial stack over a substrate, wherein the epitaxial stack comprises a semiconductor layer and a sacrificial layer over the semiconductor layer, wherein the sacrificial layer comprises a semiconductor composition different from the semiconductor layer; depositing an isolation layer over the epitaxial stack; depositing an oxide semiconductor layer over the isolation layer; and replacing a portion of the sacrificial layer and a portion of the isolation layer with a gate structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit device, comprising:
a semiconductor layer substantially free of oxygen;
an oxide semiconductor layer over and spaced apart from the semiconductor layer; and
a gate structure wrapping around a channel region of the semiconductor layer and a channel region of the oxide semiconductor layer.

2. The integrated circuit device of claim 1, wherein the semiconductor layer is GeSn, and the oxide semiconductor layer is InGaZnO.

3. The integrated circuit device of claim 1, wherein the oxide semiconductor layer is amorphous.

4. The integrated circuit device of claim 1, further comprising:
an isolation layer spacing a source/drain region of the semiconductor layer from a source/drain region of the oxide semiconductor layer.

5. The integrated circuit device of claim 1, further comprising:
a doped semiconductor layer over and in contact with a source/drain region of the semiconductor layer, wherein the doped semiconductor layer comprises a semiconductor composition different from the semiconductor layer.

6. The integrated circuit device of claim 5, further comprising:
an isolation layer spacing the doped semiconductor layer from a source/drain region of the oxide semiconductor layer.

7. The integrated circuit device of claim 1, wherein the gate structure comprises an interfacial layer in contact with the channel region of the semiconductor layer, a high-k dielectric layer over the interfacial layer and in contact with the channel region of the oxide semiconductor layer, and a gate metal layer over the high-k dielectric layer.

8. An integrated circuit device, comprising:
a p-type transistor, wherein the p-type transistor comprises at least one group-IV semiconductor layer and a first gate structure wrapping around the at least one group-IV semiconductor layer;
an isolation layer over the p-type transistor; and
a n-type transistor vertically stacked over the p-type transistor and over the isolation layer, wherein the n-type transistor comprises at least one oxide semiconductor layer and a second gate structure wrapping around the at least one oxide semiconductor layer.

9. The integrated circuit device of claim 8, wherein the oxide semiconductor layer of the n-type transistor is in contact with the isolation layer.

10. The integrated circuit device of claim 8, wherein the first gate structure is continuously connected with the second gate structure.

11. The integrated circuit device of claim 8, further comprising:
a doped semiconductor layer spacing the group-IV semiconductor layer of the p-type transistor from the isolation layer.

12. The integrated circuit device of claim 8, further comprising:
a metal layer between the oxide semiconductor layer of the n-type transistor and the isolation layer.

13. The integrated circuit device of claim 8, wherein the first gate structure wraps around a plurality of the group-IV semiconductor layers, and the group-IV semiconductor layers are vertically arranged and spaced apart from each other.

14. The integrated circuit device of claim 8, wherein the second gate structure wraps around a plurality of the oxide semiconductor layers, and the oxide semiconductor layers are vertically arranged and spaced apart from each other.

15. A method for manufacturing an integrated circuit device, comprising:
depositing an epitaxial stack over a substrate, wherein the epitaxial stack comprises a semiconductor layer and a sacrificial layer over the semiconductor layer, wherein the sacrificial layer comprises a semiconductor composition different from the semiconductor layer;
depositing an isolation layer over the epitaxial stack;
depositing an oxide semiconductor layer over the isolation layer; and
replacing a portion of the sacrificial layer and a portion of the isolation layer with a gate structure.

16. The method of claim 15, wherein replacing the portion of the sacrificial layer and the portion of the isolation layer with the gate structure comprises:
selectively etching a portion of the sacrificial layer and a portion of the isolation layer, while leaving a channel region of the semiconductor layer and a channel region of the oxide semiconductor layer exposed; and
forming the gate structure around the exposed channel region of the semiconductor layer and the exposed channel region of the oxide semiconductor layer.

17. The method of claim 16, wherein selectively etching the portion of the sacrificial layer and the portion of the isolation layer is performed using the same etch recipe.

18. The method of claim 16, wherein selectively etching the portion of the sacrificial layer and the portion of the isolation layer is performed using a plasma without substrate bias.

19. The method of claim 15, wherein depositing the oxide semiconductor layer over the isolation layer is performed such that the oxide semiconductor layer is in contact with the isolation layer.

20. The method of claim 15, wherein depositing the oxide semiconductor layer is performed such that the oxide semiconductor layer is amorphous.
